(19) United States
(12) Patent Application Publication
(10) Pub. No.: US 2010/0153625 A1
(43) Pub. Date: Jun. 17, 2010

(54) SEMICONDUCTOR MEMORY DEVICE

(75) Inventors: Masato Sugita, Kanagawa (JP); Keiji Maeda, Kanagawa (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, TOKYO (JP)

(21) Appl. No.: 12/529,083

(22) PCT Filed: Sep. 22, 2008
(86) PCT No.: PCT/JP08/67596

§ 371 Date: Aug. 28, 2009

(30) Foreign Application Priority Data
Dec. 28, 2007 (JP) 2007-340957

(51) Int. Cl. G06F 12/00; G06F 12/02; G11C 16/04; G11C 5/14; G11C 17/18

(52) U.S. Cl. 711/103; 365/185.18; 365/226; 365/225.7; 711/E12.001; 711/E12.008

(57) ABSTRACT

A semiconductor device including a plurality of flash memories, a connector for establishing connection with a host apparatus, a cache memory for data transmission between the flash memories and the host apparatus, a drive control circuit that controls the data transmission between the flash memories and the host apparatus, and a power supply circuit that converts an external power supply voltage into an internal power supply voltage, all mounted on a substrate. A fuse that protects at least the flash memories from an overcurrent is also provided on the substrate.

### TECHNICAL FIELD

The present invention relates to a semiconductor memory device such as a solid state drive (SSD) having a flash memory.

### BACKGROUND ART

An SSD that has a flash memory (flash electrically erasable programmable read only memory (EEPROM)) has attracted attention as an external or internal storage devices for a computer system, for example. The flash memory has advantages such as high speed and light weight over a magnetic disk device.

The SSD has therein a plurality of flash memory chips, a controller that performs read/write control for each of the flash memory chips according to a request from a host apparatus, a buffer memory that transmits data between each of the flash memory chips and the host apparatus, a power supply circuit, and a connection interface for connecting with the host apparatus (for example, Patent Document 1).

In the conventional SSD, however, an internal circuit cannot be protected when an overcurrent flows in the SSD. Due to the overcurrent, when a latch-up is generated in a CMOS mounting portion, malfunction of internal circuits may occur. The flash memory chips, among other internal circuits within the SSD, should be regarded in comparison with the other internal circuits as an important area to be protected from an overcurrent, because user data is stored therein.

[Patent Document 1] Japanese Patent No. 3688835

The present invention has been made in view of the above mentioned circumstance, and an object of the present invention is to provide a semiconductor memory device capable of protecting at least a flash memory portion from an overcurrent to prevent malfunction due to a latch-up and the like.

### DISCLOSURE OF INVENTION

One aspect of this invention is to provide a semiconductor memory device comprising a plurality of flash memories; a connector which is capable of connecting to a host apparatus; a cache memory for providing data transmission to the flash memories; a controller that performs control of the data transmission to the flash memories; a power supply circuit that converts an external power supply voltage into an internal power supply voltage to supply the internal power supply voltage to the flash memories; and

a fuse that protects at least the flash memories from an overcurrent, wherein the cache memory, the controller and the fuse are mounted on a substrate.

### BRIEF DESCRIPTION OF DRAWINGS

FIG. 1 is a functional block diagram of a configuration example of a semiconductor memory device according to a first embodiment of the present invention.

FIG. 2 is a plane view of a layout example of components on a substrate of the semiconductor memory device shown in FIG. 1.

FIG. 3 is a functional block diagram of a part of a configuration of a semiconductor memory device according to a second embodiment of the present invention.

### BEST MODE(S) FOR CARRYING OUT THE INVENTION

Exemplary embodiments of a semiconductor memory device according to the present invention will be explained below in detail with reference to the accompanying drawings.

### First Embodiment

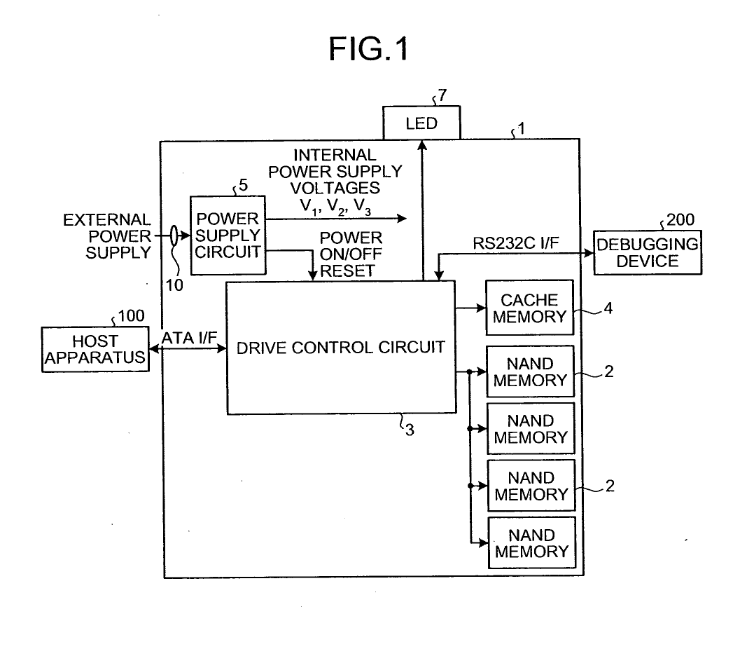

FIG. 1 is a block diagram of a functional configuration example of an internal circuit of an SSD as a semiconductor memory device according to a first embodiment of the present invention. In FIG. 1, an SSD 1 is connected to a host apparatus 100 such as a CPU core via a memory connection interface such as an At Attachment (ATA) interface, and functions as an external memory of the host apparatus 100. The SSD 1 can send data to and receive data from a debugging device 200 via a communication interface such as an RS232C interface. The SSD 1 includes a plurality of NAND flash memory chips (hereinafter, “NAND memories”) 2, a drive control circuit 3 as a controller, a cache memory 4, a power supply circuit 5, a light emitting diode (LED) 7, and a fuse 10.

Each of the NAND memories 2 has a memory cell transistor structure in which electric charges are taken in and out between a silicon substrate and a floating gate through FN (Fowler Nordheim) current that flows on a front surface of a channel. The NAND memories 2 store therein data and application programs. In this case, a single NAND memory 2 shown in FIG. 1 represents a block that performs a parallel operation, and four blocks perform four parallel operations. Each of the NAND memories 2 has for example 16 NAND memory chips mounted thereon. The cache memory 4 is configured by a dynamic random access memory (DRAM) or the like, and functions as a cache for data transmission between the host apparatus and each one of the NAND memories 2 and as a work area memory. The drive control circuit 3 controls data transmission between the host apparatus 100 and each of the NAND memories 2 via the cache memory 4, and controls components in the SSD 1. The drive control circuit 3 supplies a status display signal to a status display LED 7, and receives a power on/off reset signal from the power supply circuit 5 to supply a reset signal and a clock signal to the respective units in its own circuit and the SSD 1.

The power supply circuit 5 generates a plurality of different internal direct current (DC) power supply voltages V1, V2, and V3 (for example, 3.3V, 1.8V, and 1.2V) from an external DC power supply supplied from a power supply circuit on the side of the host apparatus 100, and supplies these internal DC power supply voltages V1, V2, and V3 to each of the circuits within the SSD 1 via a plurality of internal power supply voltage lines. The power supply circuit 5 detects a rising edge or a falling edge of an external power supply, generates a power on reset signal or a power off reset signal, and supplies the generated signal to the drive control circuit 3.

In the first embodiment, the fuse 10 is provided on the input side of the power supply circuit 5 to prevent an overcurrent, when generated, from entering into any of the internal circuits and thereby to prevent malfunction of the internal circuits due to a latch-up or the like. As the fuse 10, a power fuse that melts down due to Joule heat generated, when a current exceeding a rated current flows, may be adopted, or a self-recovery type resettable fuse (poly fuse) which does not require replacement may be adopted. As the fuse 10, for example, a fuse that melts down or cuts off a current when a current that is double the rated current plus a certain margin value flows is adopted. In the first embodiment, the fuse 10 is provided to the external power supply line on the input side of the power supply circuit 5 to protect all the internal circuits in the SSD 1 from an overcurrent.

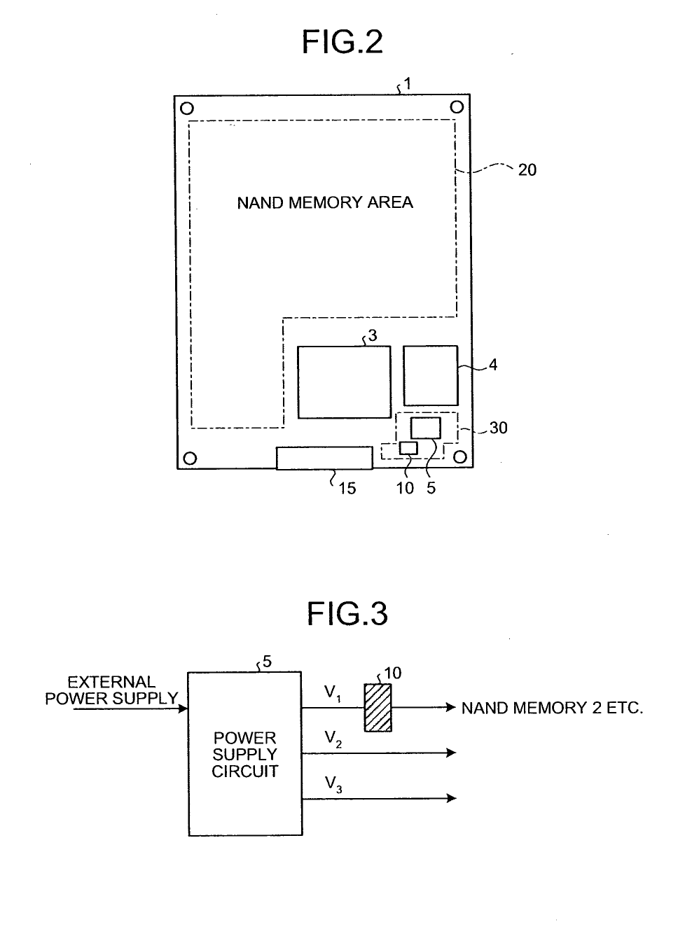

FIG. 2 is a plane view of a layout of the internal circuits of the SSD 1 shown in FIG. 1. As shown in FIG. 2, the NAND memories 2 are arranged in a NAND memory area 20 occupying most of the area of a package substrate. A connector 15 has an interface such as an ATA interface, and an RS232C formed therein. An external power supply is supplied to the power supply circuit 5 via the interfaces and an internal power supply wiring pattern, and connection is established between the host apparatus 100 or the debugging device 200 and the drive control circuit 3 via the interfaces.

The drive control circuit 3 is arranged closer to the connector 15 compared with the NAND memories 2 because the drive control circuit 3 needs to process high speed signal that is input/output via the ATA interface. The cache memory 4 is disposed adjacent to the drive control circuit 3. Because long and wide external power supply line is not preferable in terms of a layout, the power supply circuit 5 is disposed in an area 30 near the connector 15. Thus, the fuse 10 is also disposed in the area 30 near the connector 15. The NAND memory area 20 in which the NAND memories 2 are arranged is disposed around the drive control circuit 3, the cache memory 4, the power supply circuit 5, and the fuse 10. For example, the NAND memory area 20 may be disposed around the drive control circuit 3, along its long side and short side directions to maximize the memory capacity in a layout.

To conform to the size of a hard disk, area of the package substrate of the SSD is limited and, as shown in FIG. 2, the NAND memory area 20 occupies most of the area. Therefore, a number of circuits other than the NAND memory 2 have to be arranged in a small area. Generally, a power fuse that melts down is smaller than a resettable fuse. Therefore, when layout is limited as above, the layout work is easier with the power fuse.

As explained above, in the first embodiment, because the fuse 10 is provided on the input side of the power supply circuit 5 to protect all the internal circuits within the SSD 1, it is possible to protect the internal circuits within the SSD from an overcurrent so as to prevent malfunction due to a latch-up and the like. Accordingly adverse influence of heat from the latch-up on the host apparatus 100 can be prevented.

The SSD includes, a modular type provided in a substrate that is exposed without a case, and a complete product type provided in a substrate that is housed in a case. The modular type is more susceptible to noise, and latch-up occurs more frequently, compared with the complete product type. Therefore, effect of mounting the fuse 10 is more significant in the modular type.

### Second Embodiment

FIG. 3 shows a circuit configuration in periphery of the power supply circuit 5 in an SSD according to a second embodiment of the present invention. In the second embodiment, the fuse 10 is selectively provided only to an internal power supply line V1 connected to the NAND memory 2 among a plurality of internal power supply lines having different voltages (voltages V1, V2, and V3) output from the power supply circuit 5. Accordingly, even when an overcurrent occurs, at least the NAND memory 2 is protected from the overcurrent by current interruption by the fuse 10. The fuse 10 may be a power fuse or a resettable fuse.

Among the internal circuits of the SSD 1, the NAND memory 2 stores therein user data. Thus, by preventing malfunction of the NAND memory 2 by protecting it from an overcurrent by the fuse 10 provided in a post stage of the power supply circuit 5, the important user data stored in the NAND memory 2 can be taken up, and retrieved afterwards. In this case, retrieval of the data memorized in the NAND memory 2 is easier with the resettable fuse because it does not melt down like a power fuse.

Providing the fuse 10 to each one of the internal power supply lines (voltages V1, V2, and V3) output from the power supply circuit 5 facilitates an identification of a malfunctioning part. However, in the second embodiment, the fuse 10 is disposed only to a part that enables protection of at least the most important NAND memory due to the spatial issue described above.

As described above, in the second embodiment, the fuse 10 is provided in the internal power supply line to the NAND memory 2 on the output side of the power supply circuit 5 to protect at least the NAND memory 2 from an overcurrent. Accordingly, malfunction of the NAND memory 2 due to a latch-up and the like can be prevented. Accordingly, adverse influence of heat on the host apparatus 100 due to the latch-up can be prevented.

In the embodiments, the present invention is explained as being applied to the SSD having the NAND memory. The present invention may be applied to a SSD having other types of flash EEPROM such as NOR type.

According to the present invention, because the fuse is provided to protect at least a flash memory from an overcurrent, the flash memory portion can be protected from an overcurrent, and malfunction due to a latch-up and the like can be prevented.

1. A semiconductor memory device comprising:
a plurality of flash memories;
a connector which is capable of connecting to a host apparatus; a cache memory for providing data transmission to the flash memories;
a controller that performs control of the data transmission to the flash memories;
a power supply circuit that converts an external power supply voltage into an internal power supply voltage to supply the internal power supply voltage to the flash memories; and
a fuse that protects at least the flash memories from an overcurrent, wherein the cache memory, the controller and the fuse are mounted on a substrate.

2. The semiconductor memory device according to claim 1, wherein the power supply circuit, the fuse, and the controller are gathered in an certain area and provided near the connector, and the flash memories are provided to surround at least two directions of the area.

3. The semiconductor memory device according to claim 1, wherein the fuse cuts off a current when a current that is double a rated current plus a certain margin value flows.

4. The semiconductor memory device according to claim 1, wherein the fuse is a power fuse or a self-recovery type resettable fuse.

5. The semiconductor memory device according to claim 1, wherein the flash memory is a NAND type memory.

6. The semiconductor memory device according to claim 1, wherein the fuse is provided on an input side of the power supply circuit.

7. The semiconductor memory device according to claim 6, wherein the power supply circuit, the fuse, and the controller are gathered in an certain area and provided near the connector, and the flash memories are provided to surround at least two directions of the area.

8. The semiconductor memory device according to claim 6, wherein the fuse cuts off a current when a current that is double a rated current plus a certain margin value flows.

9. The semiconductor memory device according to claim 6, wherein the fuse is a power fuse or a self-recovery type resettable fuse.

10. The semiconductor memory device according to claim 6, wherein the flash memory is a NAND memory.

11. The semiconductor memory device according to claim 1, wherein
the power supply circuit has a plurality of internal power supply voltage lines that output a plurality of different internal power supply voltages, and
the fuse is provided selectively to an internal power supply voltage line that supplies the internal power supply voltage to the flash memories among the internal power supply voltage lines.

12. The semiconductor memory device according to claim 11, wherein the power supply circuit, the fuse, and the controller are gathered in an certain area and provided near the connector, and the flash memories are provided to surround at least two directions of the area.

13. The semiconductor memory device according to claim 11, wherein the fuse cuts off a current when a current that is double a rated current plus a certain margin value flows.

14. The semiconductor memory device according to claim 11, wherein the fuse is a power fuse or a self-recovery type resettable fuse.

15. The semiconductor memory device according to claim 11, wherein the flash memory is a NAND type memory.

16. The semiconductor memory device according to claim 2, wherein the fuse cuts off a current when a current that is double a rated current plus a certain margin value flows.

17. The semiconductor memory device according to claim 2, wherein the fuse is a power fuse or a self-recovery type resettable fuse.

18. The semiconductor memory device according to claim 2, wherein the flash memory is a NAND type memory.

19. The semiconductor memory device according to claim 10, wherein the fuse cuts off a current when a current that is double a rated current plus a certain margin value flows.

20. The semiconductor memory device according to claim 10, wherein the fuse is a power fuse or a self-recovery type resettable fuse.
